(19) United States
(12) Patent Application Publication
(10) Pub. No.: US 2018/0152169 A1
(43) Pub. Date: May 31, 2018

(54) SAW FILTERS WITH STEPPED-PROFILE PIEZOELECTRIC SUBSTRATE

(71) Applicant: SKYWORKS SOLUTIONS, INC., Woburn, MA (US)

(72) Inventors: Rei Goto, Osaka-Shi (JP); Hiroyuki Nakamura, Osaka-Fu (JP)

(21) Appl. No.: 15/823,693

(22) Filed: Nov. 28, 2017

Related U.S. Application Data
(60) Provisional application No. 62/484,667, filed on Apr. 12, 2017.
(60) Provisional application No. 62/427,857, filed on Nov. 30, 2016.

(51) Int. Cl. H03H 9/02; H03H 9/17; H03H 9/56

(52) U.S. Cl. CPC H03H 9/02574; H03H 9/568; H03H 9/173; H03H 9/02661

(57) ABSTRACT

A surface acoustic wave (SAW) filter having improved performance. In one example the SAW filter includes a piezoelectric substrate on which a plurality of interdigital transducer (IDT) electrodes are disposed, the piezoelectric substrate having at least two different thicknesses corresponding to regions where the plurality of IDT electrodes are disposed, and a support substrate supporting the piezoelectric substrate. In one example the piezoelectric substrate has different thicknesses selected based on respective pitches of the IDT electrodes. The piezoelectric substrate may have a flat bottom surface and top surfaces, different heights being defined between the flat bottom surface and each of the top surfaces based on the thicknesses of the piezoelectric substrate.

### CROSS REFERENCE TO RELATED APPLICATIONS

This application claims the benefit under 35 U.S.C. § 119(e) of co-pending U.S. Provisional Application No. 62/484,667 titled “SAW FILTERS WITH STEPPED-PROFILE PIEZOELECTRIC SUBSTRATE” filed on Apr. 12, 2017, and of co-pending U.S. Provisional Application No. 62/427,857 titled “SAW FILTERS WITH STEPPED-PROFILE PIEZOELECTRIC SUBSTRATE” filed on Nov. 30, 2016, each of which is herein incorporated by reference in its entirety for all purposes.

### BACKGROUND

Conventionally, in a communications device such as a mobile phone, a filter device has been used to separate signals having different bands, such as a transmission signal and a reception signal, for example. A surface acoustic wave (SAW) filter including a SAW resonator has been used for such a filter device. The SAW resonator includes an interdigital transducer (IDT) electrode formed on a piezoelectric substrate made of lithium niobate (LiNbO₃) or lithium tantalate (LiTaO₃). The SAW filter has been provided as a ladder-type filter, a double mode SAW (DMS) filter, and the like.

### SUMMARY OF INVENTION

Aspects and embodiments relate to a surface acoustic wave (SAW) filter used in a communications device.

There has been a need to further improve the performance of a SAW filter in order to keep up with desired performance improvements in communications devices. For example, there has been a need to improve the attenuation and the insertion loss of the SAW filter. Accordingly, aspects and embodiments are directed to further improving the performance of a SAW filter.

According to certain embodiments, a SAW filter includes a piezoelectric substrate on which a plurality of interdigital transducer (IDT) electrodes are disposed, the piezoelectric substrate having at least two different thicknesses corresponding to different regions where the plurality of IDT electrodes are disposed, and a support substrate supporting the piezoelectric substrate. The at least two different thicknesses of the piezoelectric substrate can be configured to optimize the performance of the SAW filter.

According to one embodiment a surface acoustic wave (SAW) filter comprises a support substrate, a piezoelectric substrate disposed on and supported by the support substrate, the piezoelectric substrate including a first region having a first thickness and a second region having a second thickness different from the first thickness, and a plurality of interdigital transducer (IDT) electrodes disposed on the piezoelectric substrate.

In one example a first IDT electrode of the plurality of IDT electrodes is disposed on the first region of the piezoelectric substrate and a second IDT electrode of the plurality of IDT electrodes is disposed on the second region of the piezoelectric substrate. In another example the first IDT electrode includes first IDT electrode fingers having a first pitch and the second IDT electrode includes second IDT electrode fingers having a second pitch, the second pitch being different from the first pitch. In another example the first pitch is greater than the second pitch, and the first thickness is greater than the second thickness. In one example the piezoelectric substrate has a first surface abutting the support substrate and a second surface, the second surface being disposed at a first height above the first surface in the first region and at a second height above the first surface in the second region, and the first height being defined by the first thickness and the second height being defined by the second thickness. In one example the piezoelectric substrate has a first flat surface and a second surface that abuts the support substrate, the second surface being disposed a first distance away from the flat first surface in the first region and a second distance away from the flat first surface in the second region, the first distance being defined by the first thickness and the second distance being defined by the second thickness.

In another example the support substrate includes first structural layer configured to mechanically support the piezoelectric substrate. In one example the first structural layer is made of one of silicon, sapphire, or diamond. In another example the support substrate further includes a second structural layer interposed between the first structural layer and the piezoelectric substrate. In another example the second structural layer has a lower sound velocity than the first structural layer. In one example the second structural layer is made of silicon dioxide. In another example the support substrate further includes a gap layer positioned between the first structural layer and the second structural layer. In another example the support substrate further includes at least one spacer configured to space the second structural layer apart from the first structural layer to form the gap layer. In one example the gap layer is an air gap layer. In another example the gap layer is configured to reflect at least one acoustic wave within the second structural layer.

The SAW filter may further comprise a cover layer disposed on the piezoelectric substrate. In one example the cover layer has a lower sound velocity than the first structural layer. In another example the cover layer is made of silicon dioxide. In another example the support substrate includes first structural layer configured to mechanically support the piezoelectric substrate, and the cover layer includes a second structural layer. In one example the second structural layer is made of one of silicon, sapphire, and diamond.

In another example the support substrate includes stack of a plurality of first layers and a plurality of second layers alternately arranged abutting one another, each of the plurality of first layers having a first sound velocity and each of the plurality of second layers having a second sound velocity, the first sound velocity being lower than the second sound velocity. In one example each of the plurality of second layers is made of one of silicon, sapphire, and diamond. In another example each of the plurality of second layers is made of silicon dioxide. The stack can be configured to reflect at least one acoustic wave towards the piezoelectric substrate.

In one example the piezoelectric substrate is made of one of lithium niobate (LiNbO3) and lithium tantalite (LiTaO3).

In another example the SAW filter is a ladder-type filter. In one example the ladder-type filter includes a plurality of series-arm resonators connected in series with one another along a signal path extending between an input of the ladder-type filter and an output of the ladder-type filter, the ladder-type filter further including a plurality of parallel-arm resonators connected between the signal path and a ground, the plurality of series-arm resonators being disposed on the first region of the piezoelectric substrate, and the plurality of parallel-arm resonator being disposed on the second region of the piezoelectric substrate.

Further embodiments are directed to a module comprising an example of the SAW filter.

Further embodiments are directed to an antenna duplexer comprising an input contact, an output contact, and a common contact, a transmission filter connected between the input contact and the common contact; and a reception filter connected between the common contact and the output contact, at least one of the reception filter and the transmission filter including an example of the SAW filter.

Further embodiments are directed to a front-end module comprising an example of the antenna duplexer. In one example the front-end module includes a transceiver, the transceiver including a transmission circuit connected to the input contact of the antenna duplexer and a reception circuit connected to the output contact of the antenna duplexer.

Certain embodiments are directed to a wireless electronic device comprising an example of the front-end module. The wireless electronic device may further comprise an antenna connected to the common contact of the antenna duplexer.

According to another embodiment a method of manufacture of a surface acoustic wave (SAW) filter comprises acts of stacking a piezoelectric substrate on a support substrate, the piezoelectric substrate having a first region and a second region, etching a surface of the piezoelectric substrate in the first region to reduce a thickness of the piezoelectric substrate in the first region relative to the second region, and forming a plurality of IDT electrodes on the piezoelectric substrate including forming a first interdigital transducer (IDT) electrode in the first region and forming a second IDT electrode in the second region, the first IDT electrode having a first electrode-finger pitch and the second IDT electrode having a second electrode-finger pitch, the first electrode-finger pitch being smaller than the second electrode-finger pitch.

In one example the method further comprises an act of stacking a second structural layer on a first structural layer to form the support substrate, and wherein stacking the piezoelectric substrate on the support substrate includes stacking the piezoelectric substrate on the second structural layer. In another example the method further comprises an act of forming a gap between the first structural layer and the second structural layer by forming at least one spacer on the first structural layer, the at least one spacer being configured to space apart the second structural layer from the first structural layer. In one example etching the surface of the piezoelectric substrate is performed prior to stacking the piezoelectric substrate on the support substrate. In another example etching the surface of the piezoelectric substrate is performed after stacking the piezoelectric substrate on the support substrate. The method may further comprise acts of alternately stacking a plurality of first layers on a plurality of second layers to form the support substrate, each of the plurality of first layers having a first sound velocity and each of the plurality of second layers having a second sound velocity, the first sound velocity being higher than the second sound velocity. The method may further comprise an act of stacking a cover layer on the piezoelectric substrate.

According to another embodiment an antenna duplexer comprises an input contact, an output contact, and a common contact, a support substrate, a piezoelectric substrate disposed on and mechanically supported by the support substrate, the piezoelectric substrate including a first region having a first thickness and a second region having a second thickness different from the first thickness, a transmission filter connected between the input contact and the common contact, the transmission filter including at least one transmission resonator having a first interdigital transducer (IDT) electrode disposed on the first region of the piezoelectric substrate, and a reception filter connected between the common contact and the output contact, the reception filter including at least one reception resonator having a second IDT electrode disposed on the second region of the piezoelectric substrate. In one example the first thickness is less than the second thickness, the first IDT electrode has a first electrode-finger pitch, and the second IDT electrode has a second electrode-finger pitch that is greater than the first electrode-finger pitch.

Still other aspects, embodiments, and advantages of these exemplary aspects and embodiments are discussed in detail below. Embodiments disclosed herein may be combined with other embodiments in any manner consistent with at least one of the principles disclosed herein, and references to “an embodiment,” “some embodiments,” “an alternate embodiment,” “various embodiments,” “one embodiment” or the like are not necessarily mutually exclusive and are intended to indicate that a particular feature, structure, or characteristic described may be included in at least one embodiment. The appearances of such terms herein are not necessarily all referring to the same embodiment.

### BRIEF DESCRIPTION OF DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the invention. In the figures, each identical or nearly identical component that is illustrated in various figures is represented by a like numeral. For purposes of clarity, not every component may be labeled in every figure. In the figures:

FIG. 1 is a cross-sectional view showing a schematic structure of an example of a surface acoustic wave (SAW) filter according to certain embodiments;

FIG. 2 is a graph showing a dependency of electromechanical coupling coefficient on a thickness of the piezoelectric substrate;

FIG. 3A is a flow diagram illustrating one example of a method of fabricating a SAW filter, such as that shown in FIG. 1, according to certain embodiments;

FIG. 3B is a flow diagram illustrating another example of a method of fabricating the SAW filter according to certain embodiments;

FIG. 4 is a schematic block diagram of one example of a ladder-type filter that can be constructed using a SAW filter according to certain embodiments;

FIG. 5 is a cross-sectional view showing a schematic structure of one example of a SAW filter according to certain embodiments;

FIG. 6 is a cross-sectional view showing a schematic structure of another example of a SAW filter according to certain embodiments;

FIG. 7 is a cross-sectional view showing a schematic structure of another example of a SAW filter according to certain embodiments;

FIG. 8 is a cross-sectional view showing a schematic structure of another example of a SAW filter according to certain embodiments;

FIG. 9 is a cross-sectional view showing a schematic structure of another example of a SAW filter according to certain embodiments;

FIG. 10 is a cross-sectional view showing a schematic structure of another example of a SAW filter according to certain embodiments;

FIG. 11 is a block diagram of one example of a packaged module including the SAW filter according to various embodiments;

FIG. 12 is a block diagram of one example of a front-end module including an antenna duplexer implemented using examples of the SAW filter according to certain embodiments; and

FIG. 13 is a block diagram of one example of a wireless device in which examples of the SAW filter can be used according to various embodiments.

### DETAILED DESCRIPTION

Aspects and embodiments are directed to surface acoustic wave (SAW) filters, and to modules and electronic devices incorporating same. In particular, aspects and embodiments are directed to SAW filters constructed from two or more SAW resonators in which the piezoelectric substrate on which the SAW resonators are formed has different thicknesses in different regions, such that the piezoelectric substrate has a “stepped” profile in cross-section, as shown in the accompanying figures. Interdigital transducer (IDT) electrodes formed on the different regions of the piezoelectric substrate with different thicknesses may have different electrode finger pitches, as discussed further below. As used herein, the term “pitch” refers to the distance between edges of adjacent electrode fingers, as discussed further below. Larger pitch means that the electrode fingers are spaced further apart from one another.

Various embodiments of surface acoustic wave (SAW) filters according to aspects of the present invention are described below in detail with reference to the drawings.

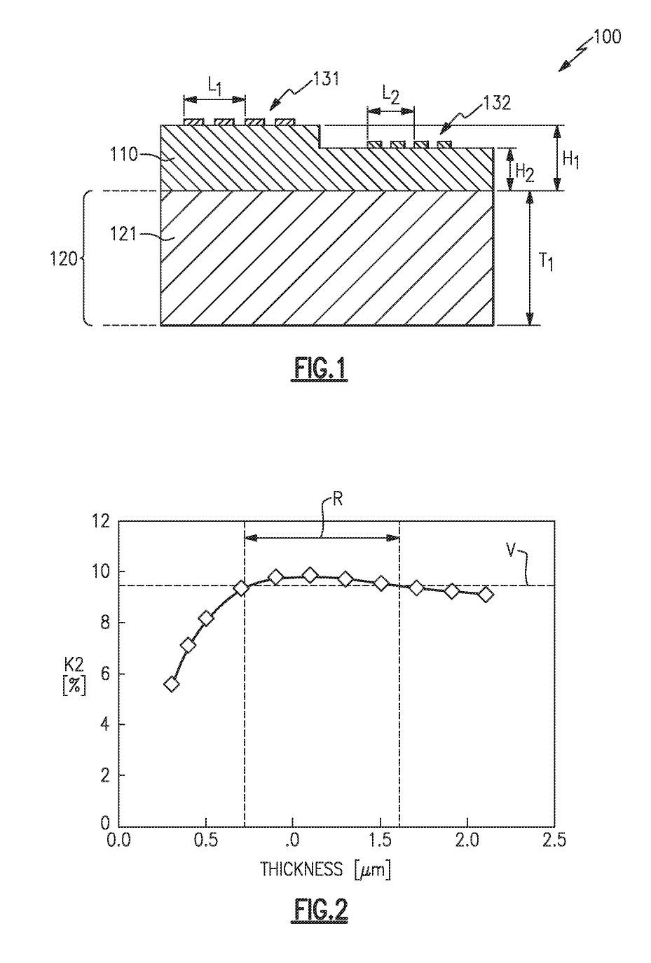

FIG. 1 is a cross-sectional view showing a schematic structure of a SAW filter according to certain embodiments. As shown in FIG. 1, the SAW filter 100 includes a piezoelectric substrate 110 made of a piezoelectric body material such as lithium niobate (LiNbO₃) or lithium tantalate (LiTaO₃), and which is supported by a support substrate 120. According to one embodiment, the support substrate 120 includes a first structural layer 121 having a certain thickness T₁. The first structural layer 121 may be made of silicon, sapphire, or diamond, for example, and provides a structure to mechanically support the piezoelectric substrate 110. A plurality of interdigital transducer (IDT) electrodes 131, 132 are disposed on top surfaces of the piezoelectric substrate 110 to form respective SAW resonators. As known to those skilled in the art, each IDT electrode includes a pair of interdigitated comb-shaped electrodes, with each comb-shaped electrode including a plurality of electrode fingers that extend from a bus-bar, the electrode fingers of the two comb-shaped electrodes being interdigitated with one another. It is to be appreciated that, although two IDT electrodes 131, 132 are shown in the FIG. 1, embodiments of the SAW filters disclosed herein may include two or more IDT electrodes disposed on the top surfaces of the piezoelectric substrate 110 in a suitable arrangement.

In the SAW filter 100 shown in FIG. 1, the piezoelectric substrate 110 has a flat bottom surface abutting the support substrate 120 and top surfaces formed at different heights above the bottom surface. The different heights can be defined such that regions of the piezoelectric substrate 110 where each of the IDT electrodes 131, 132 is disposed can have suitable respective thicknesses depending on an electrode-finger pitch of the corresponding IDT electrode. A first IDT electrode 131 has a first electrode-finger pitch L₁ and a second IDT electrode 132 has a second electrode-finger pitch L₂. The pitch is defined as the distance from an edge of one electrode finger to the same-side edge of an adjacent electrode finger connected to the same bus-bar. In one example, as shown in FIG. 1, the pitch L₁ of the IDT electrode 131 is greater than the pitch L₂ of the IDT electrode 132 (L₁>L₂) and a height H₁ defined between the flat bottom surface and a first top surface of the piezoelectric substrate 110 corresponding to a region where the IDT electrode 131 is disposed is configured to be greater than a height H₂ defined between the flat bottom surface (abutting the support substrate 120) and a second top surface of the piezoelectric substrate 110 corresponding to a region where the IDT electrode 132 is disposed (H₁>H₂). In other words, as shown in FIG. 1, the thickness of the piezoelectric substrate 110 in the region where the IDT electrode 131 is disposed is configured to be greater than the thickness of the piezoelectric substrate 110 in the region where the IDT electrode 132 is disposed.

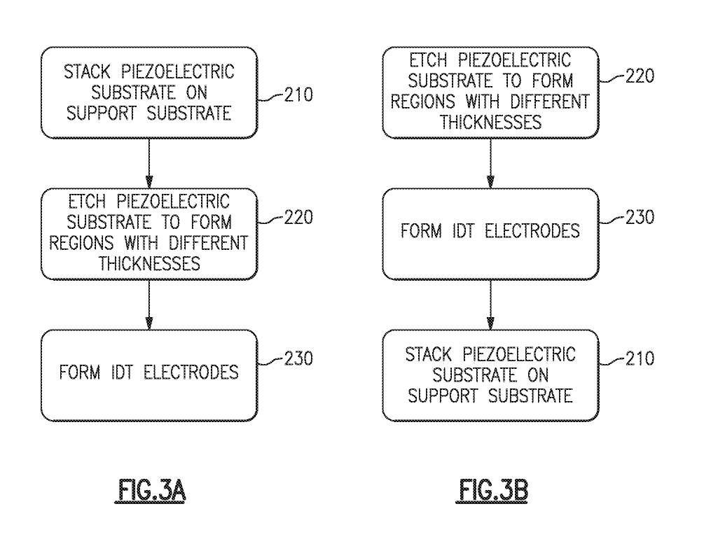

FIG. 2 is a graph showing a relationship between a thickness of the piezoelectric substrate 110 (horizontal axis) and an electromechanical coupling coefficient (K2; vertical axis). The graph illustrates how, for an IDT electrode with a certain pitch, the electromechanical coupling coefficient depends on and varies with the thickness of the piezoelectric substrate 110. As can be seen in the graph, the electromechanical coupling coefficient may be greater than or equal to a certain value V when the thickness of the piezoelectric substrate 110 is configured to be within a certain suitable range R. The values of V and R may change for IDT electrodes with different electrode-finger pitches.

According to one embodiment, the thicknesses of the piezoelectric substrate 110 in the regions where the IDT electrodes 131, 132 are disposed, i.e., the heights H₁, H₂ corresponding to the respective thicknesses, are optimized to allow the electromechanical coupling coefficients (K2) for the IDT electrodes 131, 132 to be suitable values. This can be achieved, for example, by configuring the thicknesses (H₁, H₂) of the piezoelectric substrate 110 in the regions where the IDT electrodes 131, 132 are disposed to be within the range R. Therefore, the performance of the SAW resonator formed by the IDT electrodes 131, 132 can be improved, and thus the performance of the SAW filter 100 can be improved as well. For example, the attenuation and the insertion loss resulting from the SAW filter 100 can be improved.

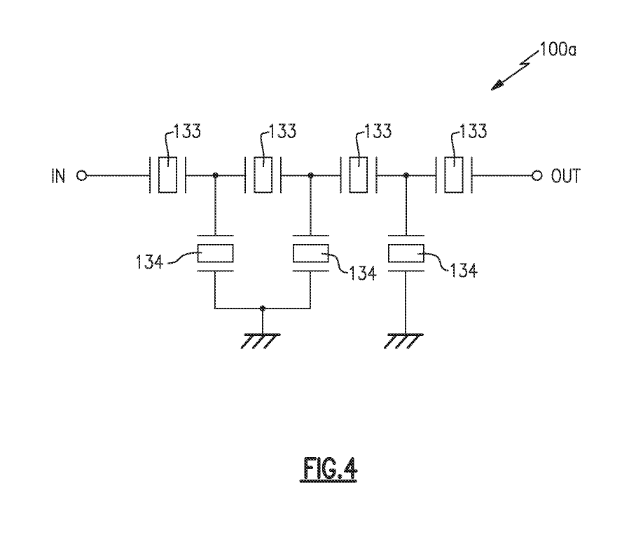

Embodiments of the SAW filters disclosed herein may be fabricated, for example, according to the following process. Referring to FIG. 3A, in a step 210 the piezoelectric substrate 110 is stacked on the support substrate 120. Subsequently in step 220 the piezoelectric substrate 110 is etched to have top surfaces positioned at suitable heights, as shown in FIG. 1, for example. In step 230 the IDT electrodes 131, 132 are then formed on the top surfaces. In another example, rather than performing step 210 first, the piezoelectric substrate 110 that has been formed to have suitable thicknesses and provided with the IDT electrodes 131, 132 (steps 220 and 230) may be subsequently bonded onto the support substrate 120. In other words, step 210 may be performed following steps 220 and 230, as shown in FIG. 3B, rather than before steps 220 and 230.

In the above-discussed example of the SAW filter 100 shown in FIG. 1, the piezoelectric substrate 110 includes two regions of different thicknesses with one respective IDT electrode 131, 132 disposed in each region, and the different thicknesses are selected based on the pitches of the respective IDT electrodes. However, it is to be appreciated that embodiments of the SAW filter 100 are not limited to this arrangement. In other embodiments, the piezoelectric substrate 110 can include two or more regions of different thicknesses, and multiple IDT electrodes can be disposed in any one or more of the regions. In such a case, the performance of the SAW filter can be improved by adjusting the different thicknesses of the piezoelectric substrate 110 based on the pitches of at least some of the IDT electrodes.

According to certain embodiments, the SAW filter 100 can be configured to form a ladder-type filter, such as that shown in FIG. 4. In such an example, the SAW filter 100a may include a plurality of series-arm IDT electrodes 133 and a plurality of parallel-arm IDT electrodes 134 that are constructed and arranged to provide the SAW filter 100a with a passband and a stopband. As the frequency response of the series-arm IDT electrodes 133 and the parallel-arm IDT electrodes 134 may depend at least in part on the electrode-finger pitch of the IDT electrodes, in certain examples, the series-arm IDT electrodes 133 may have different pitches than do the parallel-arm IDT electrodes 134. Accordingly, the SAW filter 100a can be configured such that the series-arm IDT electrodes 133 are disposed in a first region of the piezoelectric substrate 110, and the parallel-arm IDT electrodes 134 are disposed in a second region of the piezoelectric substrate. In such an example, the piezoelectric substrate 110 may have a first thickness in the first region, and a second thickness, different from the first thickness, in the second region. The performance of the ladder-type filter 100a can be improved by suitably adjusting the different thicknesses of the piezoelectric substrate 110.

Further, embodiments of the SAW filter 100 can be configured to form a multi-filter device, such as an antenna duplexer, for example. The multi-filter device may include a transmission filter and a reception filter, for example. The transmission filter and reception filter may have different frequency responses. For example, the passbands of the transmission filter and the reception filter, respectively, may span different frequency ranges. Accordingly, the IDT electrode(s) used to form each of the transmission filter and the reception filter may have different pitches. In such an embodiment, the piezoelectric substrate 110 may have different thicknesses between a first region where IDT electrodes forming the transmission filter are disposed and a second region where IDT electrodes forming the reception filter are disposed. The performance of such a multi-filter device can be improved by suitably adjusting the thicknesses of the different regions of the piezoelectric substrate 110, as discussed above.

FIG. 5 is a cross-sectional view showing a schematic structure of another example of a SAW filter 100 according to certain embodiments. As discussed above with reference to FIG. 1, the support substrate 120 may include a first structural layer 121. In the example shown in FIG. 5, the support substrate 120 further includes an additional layer 122 stacked on the first structural layer 121, as discussed further below.

Referring to FIG. 5, according to one embodiment, the piezoelectric substrate 110 made of a piezoelectric body material, such as lithium niobate or lithium tantalate for example, is supported by the support substrate 120. The support substrate 120 includes a first structural layer 121 made of silicon, sapphire or diamond, for example, and having a certain thickness selected to provide a structure to mechanically support the piezoelectric substrate 110. The support substrate 120 further includes a first lower-sound-velocity layer 122 disposed on the top surface of the first structural layer 121. The first lower-sound-velocity layer 122 is characterized by a sound velocity (i.e., a velocity at which sound propagates through the layer) lower than that of the first structural layer 121. The first structural layer 121 may thus be referred to as a higher-sound-velocity layer because it is characterized by a sound velocity higher than that of the first lower-sound-velocity layer 122. The first lower-sound-velocity layer 122 has a certain thickness and may be made of silicon dioxide, for example.

Also as shown in FIG. 5, the IDT electrodes 131, 132 are disposed on top surfaces of the piezoelectric substrate 110 to form respective SAW resonators, as discussed above. As in the example shown in FIG. 1, in this example, the piezoelectric substrate 110 has a flat bottom surface abutting the support substrate 120 and top surfaces arranged at different heights above the flat bottom surface. Thus, the piezoelectric substrate 110 has a “stepped” profile. As discussed above, the different heights between the bottom surface and the respective top surfaces of the piezoelectric substrate 110 are defined such that a region where each of the IDT electrodes 131, 132 is disposed can have a suitable thickness depending on a pitch of the corresponding IDT electrode. Therefore, the performance of the SAW resonator formed by the IDT electrodes 131, 132 and thus the performance of the SAW filter 100 can be improved.

According to one example, the first lower-sound-velocity layer 122 is made of silicon dioxide and is disposed directly under the piezoelectric substrate 110 in the support substrate 120. Thus, the bottom surface of the piezoelectric substrate 110 abuts the top surface of the first lower-sound-velocity layer 122, as shown in FIG. 5. This configuration can improve the temperature characteristics of the SAW resonator formed by the IDT electrodes 131, 132 and thus of the SAW filter 100. Further, because the first lower-sound-velocity layer 122 is disposed directly under and in contact with the piezoelectric substrate 110, the SAW resonator formed by the IDT electrodes 131, 132, and thus the SAW filter 100, can be less sensitive to the thickness of the piezoelectric substrate 110.

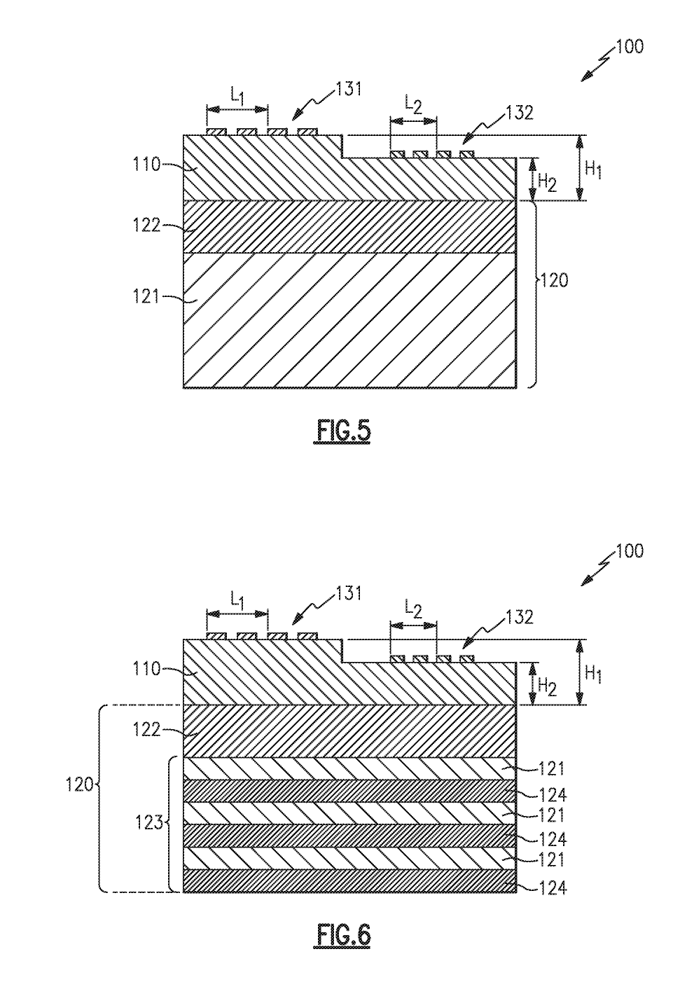

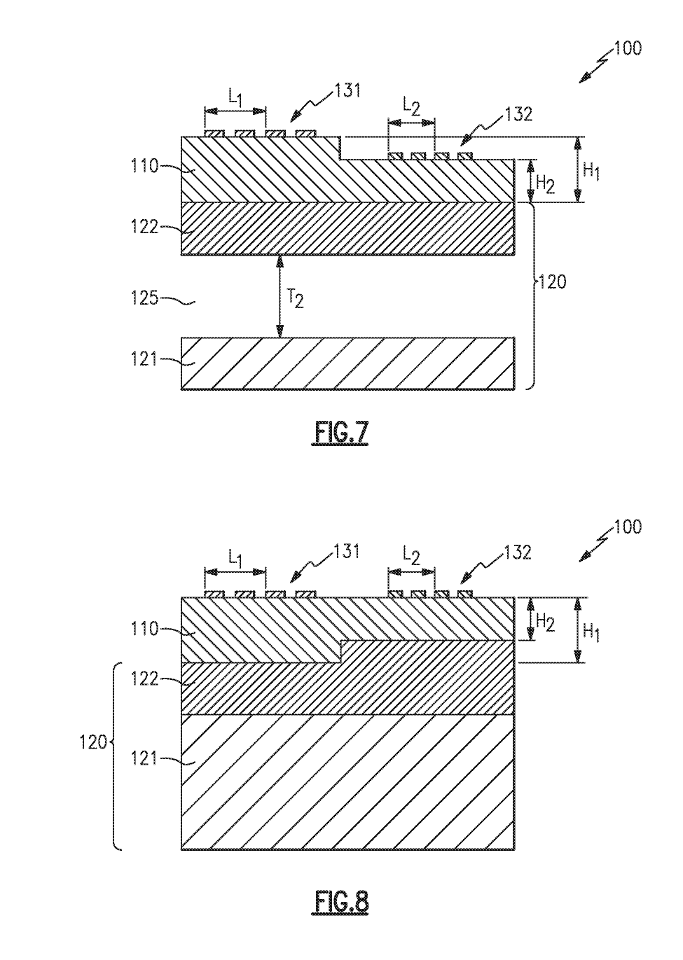

FIG. 6 is a cross-sectional view showing a schematic structure of another example of a SAW filter 100 according to certain embodiments. In this example, the support substrate 120 includes multiple layers 123, and the first lower-sound-velocity layer 122 is stacked on the multiple layers 123.

As discussed above, the piezoelectric substrate 110 can be made of a piezoelectric body material such as lithium niobate or lithium tantalate, and is supported by the support substrate 120. In the example shown in FIG. 6, the support substrate 120 includes multiple layers 123 formed by alternately stacking a first structural layer 121 made of silicon, sapphire or diamond with a second lower-sound-velocity layer 124 made of silicon dioxide. The second lower-sound-velocity layer 124 is characterized by a sound velocity lower than that of the first structural layer 121. The support substrate 120 further includes the first lower-sound-velocity layer 122 disposed on the top surface of the stack of multiple layers 123. As discussed above, the first lower-sound-velocity layer 122 has a certain thickness, may be made of silicon dioxide, and is characterized by a sound velocity lower than that of the first structural layer 121. The first structural layer 121 may be referred to as a higher-sound-velocity layer because it is characterized by a sound velocity higher than either of the first lower-sound-velocity layer 122 and the second lower-sound-velocity layer 124.

Also shown in FIG. 6, the IDT electrodes 131, 132 are disposed on top surfaces of the piezoelectric substrate 110 to form respective SAW resonators, as discussed above. The piezoelectric substrate 110 has a flat bottom surface abutting the support substrate 120 and top surfaces arranged at different suitable heights (H₁, H₂) above the flat bottom surface. Thus, the piezoelectric substrate 110 has a “stepped” profile, as discussed above. The different heights (H₁, H₂) are defined such that respective regions of the piezoelectric substrate 110 where each of the IDT electrodes 131, 132 are disposed can have suitable thicknesses depending on a pitch of the corresponding IDT electrode. Therefore, the performance of the SAW resonator formed by the IDT electrodes 131, 132, and thus the performance of the SAW filter 100, can be improved.

According to one example, the first lower-sound-velocity layer 122 is made of silicon dioxide and is disposed directly under the piezoelectric substrate 110 in the support substrate 120, as shown in FIG. 6. This configuration can improve the temperature characteristics of the SAW resonator formed by the IDT electrodes 131, 132, and thus of the SAW filter 100. Further, the multiple layers 123 included in the support substrate 120 may have an effect on an acoustic wave allowed to be reflected and confined in the first lower-sound-velocity layer 122 such that the SAW filter 100 may be made thinner.

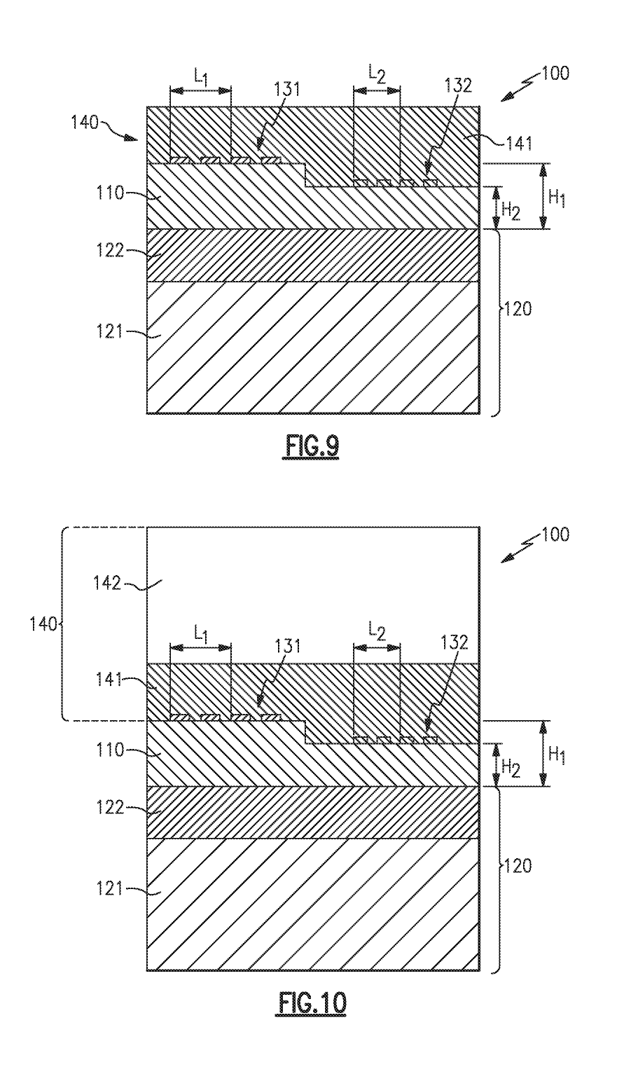

FIG. 7 is a cross-sectional view showing a schematic structure of another example of the SAW filter 100 according to certain embodiments. In this example the support substrate 120 includes a first structural layer 121, and a gap layer 125 and a first lower-sound-velocity layer 122 both stacked on and above the first structural layer 121.

In the example shown in FIG. 7, the piezoelectric substrate 110 is made of a piezoelectric body material, such as lithium niobate or lithium tantalate, for example, and is supported by the support substrate 120. In this example the support substrate 120 includes the first structural layer 121 having a certain thickness and made of silicon, sapphire or diamond, and the first lower-sound-velocity layer 122 also having a certain thickness and disposed directly below (abutting the bottom surface of) the piezoelectric substrate 110. The support substrate 120 further includes a gap layer 125 interposed between the top surface of the first structural layer 121 and the bottom surface of the first lower-sound-velocity layer 122 so as to define a certain height T₂ between the first structural layer 121 and the first lower-sound-velocity layer 122. The gap layer 125 can be formed by a suitable spacer and the like (not shown in FIG. 7). In some examples the gap layer 125 may be referred to as an air gap because air is included in the gap/space between the first structural layer 121 and the first lower-sound-velocity layer 122. The first lower-sound-velocity layer 122 can be made of silicon dioxide and, as discussed above, is characterized by a sound velocity lower than that of the first structural layer 121. Further, the first structural layer 121 may be referred to as a higher-sound-velocity layer because it is characterized by a sound velocity higher than that of the first lower-sound-velocity layer 122.

Also in this example, the IDT electrodes 131, 132 are disposed on top surfaces of the piezoelectric substrate 110 to form respective SAW resonators. The piezoelectric substrate 110 has a flat bottom surface that abuts the top surface of the support substrate 120 and top surfaces disposed at suitable heights (H₁, H₂) above the flat bottom surface. As discussed above, the different heights (H₁, H₂) are defined such that regions of the piezoelectric substrate 110 where each of the IDT electrodes 131, 132 are disposed can have suitable thicknesses depending on a pitch of the corresponding IDT electrode. As a result of this structure, the performance of the SAW resonator formed by the IDT electrodes 131, 132, and thus the performance of the SAW filter 100, can be improved.

As shown in FIG. 7, the first lower-sound-velocity layer 122, which may be made of silicon dioxide, is disposed directly under the piezoelectric substrate 110 in the support substrate 120. This arrangement can improve the temperature characteristics of the SAW resonator formed by the IDT electrodes 131, 132, and thus of the SAW filter 100. Further, the first lower-sound-velocity layer 122 and the gap layer 125 disposed directly under the piezoelectric substrate 110 may have an effect on an acoustic wave allowed to be reflected by a boundary between the first lower-sound-velocity layer 122 and the gap layer 125 and confined in the first lower-sound-velocity layer 122, such that the SAW filter 100 may be made thinner.

FIG. 8 is a cross-sectional view showing a schematic structure of another example of the SAW filter 100 according to certain embodiments. In this example, the support substrate 120 includes a first structural layer 121 and a first lower-sound-velocity layer 122 stacked on the first structural layer 121. In addition, in this example the piezoelectric substrate 110 is configured to have a flat top surface, with bottom surfaces spaced at different heights from the flat top surface. This is in contrast to the examples discussed above, and as shown in FIG. 1, for example, in which the piezoelectric substrate 110 has a flat bottom surface with different heights being defined between the flat bottom surface and the respective top surfaces.

In the example shown in FIG. 8, the piezoelectric substrate 110 has a flat top surface on which the IDT electrodes 131, 132 are formed. The piezoelectric substrate 110 further has bottom surfaces spaced at different suitable heights from the flat top surface such that a region where each of the IDT electrodes 131, 132 is disposed can have a suitable thickness depending on a pitch of the corresponding IDT electrodes. As shown in FIG. 8, a pitch L₁ of the IDT electrode 131 is greater than a pitch L₂ of the IDT electrode 32 (L₁>L₂) and a height H₁ defined between the top surface and a bottom surface of the piezoelectric substrate 110 corresponding to the region where the IDT electrode 131 is disposed is configured to be greater than a height H₂ defined between the top surface and a bottom surface of the piezoelectric substrate 110 corresponding to the region where the IDT electrode 132 is disposed (H₁>H₂). In other words, the thickness of the piezoelectric substrate 110 corresponding to the region where the IDT electrode 131 is disposed is configured to be greater than the thickness of the piezoelectric substrate 110 corresponding to the region where the IDT electrode 132 is disposed.

As discussed above, the piezoelectric substrate 110 is made of piezoelectric body such as lithium niobate or lithium tantalate and is supported by the support substrate 120. In the example of FIG. 8, the support substrate 120 includes a first structural layer 121 made of silicon, sapphire or diamond and having a certain thickness for providing a structure to mechanically support the piezoelectric substrate 110. The support substrate 120 further includes a first lower-sound-velocity layer 122 disposed on a top surface of the first structural layer 121. The first lower-sound-velocity layer 122 has a certain thickness, may be made of silicon dioxide, and is characterized by a sound velocity lower than that of the first structural layer 121. Thus, the first structural layer 121 may be referred to as a higher-sound-velocity layer because it is characterized by a sound velocity higher than that of the first lower-sound-velocity layer 122.

According to this example, the piezoelectric substrate 110 is configured to have a flat top surface and bottom surfaces disposed at suitable heights relative to the flat top surface. As discussed above, the different heights between the top surface and the respective bottom surfaces are defined such that the region where each of the IDT electrodes 131, 132 is disposed can have a suitable thickness depending on the pitch of the corresponding IDT electrode. Therefore, the performance of the SAW resonator formed by the IDT electrodes 131, 132 can be improved, and thus the performance of the SAW filter 100 can be improved.

As discussed above, in this example, the piezoelectric substrate 110 has a flat top surface, with different heights being defined between the flat top surface and the respective bottom surfaces. This allows the IDT electrodes 131, 132 to be disposed together on a single top surface of the piezoelectric substrate 110 such that the manufacturing process can be simplified. Here, the bottom surfaces of the piezoelectric substrate 110 may be fabricated by applying a trimming on the piezoelectric substrate 110 having a certain thickness such that the different heights can be defined. Further, in another fabrication process, the first lower-sound-velocity layer 122 may be etched for the top surfaces to define different heights and the piezoelectric substrate 110 having a flat top surface may be stacked on the etched first lower-sound-velocity layer 122.

According to one example, the first lower-sound-velocity layer 122 can be made of silicon dioxide and is disposed directly under and abutting the piezoelectric substrate 110 in the support substrate 120. This arrangement can improve the temperature characteristics of the SAW resonator formed by the IDT electrodes 131, 132, and thus also of the SAW filter 100. Further, because the first lower-sound-velocity layer 122 is disposed directly under and in contact with the piezoelectric substrate 110, the SAW resonator formed by the IDT electrodes 131, 132, and therefore the SAW filter 100, may be less sensitive to the thickness of the piezoelectric substrate 110.

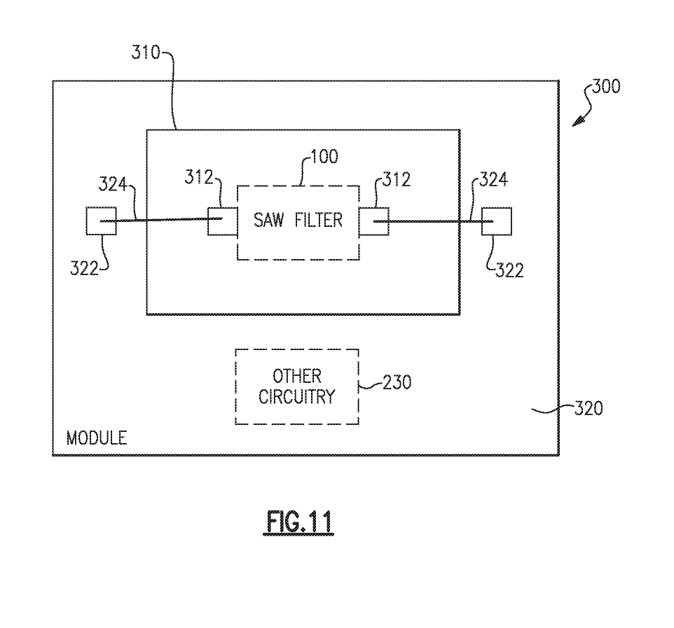

FIG. 9 is a cross-sectional view showing a schematic structure of another example of the SAW filter 100 according to certain embodiments. In this example the support substrate 120 includes a first structural layer 121 and a first lower-sound-velocity layer 122 stacked on the first structural layer 121. In addition, a cover layer 140 including a third lower-sound-velocity layer 141 is disposed on the piezoelectric substrate 110.

In the example shown in FIG. 9, the piezoelectric substrate 110, which is made of a piezoelectric body material such as lithium niobate or lithium tantalite, is supported by the support substrate 120. The support substrate 120 includes the first structural layer 121 made of silicon, sapphire or diamond and having a certain thickness for providing a structure to mechanically support the piezoelectric substrate 110. As discussed above, the support substrate 120 further includes the first lower-sound-velocity layer 122 disposed on the top surface of the first structural layer 121. The first lower-sound-velocity layer 122 has a certain thickness, is made of silicon dioxide, and is characterized by a sound velocity lower than that of the first structural layer 121. Thus, as discussed above, the first structural layer 121 may be referred to as a higher-sound-velocity layer because it is characterized by a sound velocity higher than that of the first lower-sound-velocity layer 122.

IDT electrodes 131, 132 are disposed on the top surfaces of the piezoelectric substrate, as discussed above. According to the example of FIG. 9, a cover layer 140 defining a certain height is disposed on the top surfaces of the piezoelectric substrate 110 to cover the IDT electrodes 131, 132. The cover layer 140 includes a third lower-sound-velocity layer 141 made of silicon dioxide and characterized by a sound velocity lower than that of the first structural layer 121.

Also in this example, the piezoelectric substrate 110 has a flat bottom surface abutting the top surface of the support substrate 120 and top surfaces arranged at different suitable heights (H₁, H₂) above the flat bottom surface. Thus, the piezoelectric substrate 110 has a “stepped” profile, as discussed above. The different heights (H₁, H₂) are defined such that respective regions of the piezoelectric substrate 110 where each of the IDT electrodes 131, 132 are disposed can have suitable thicknesses depending on a pitch of the corresponding IDT electrode. Therefore, the performance of the SAW resonator formed by the IDT electrodes 131, 132 can be improved, and thus the performance of the SAW filter 100 can be improved.

According to the example of FIG. 9, the first lower-sound-velocity layer 122 made of silicon dioxide is disposed directly under the piezoelectric substrate 110 in the support substrate 120, and the third lower-sound-velocity layer 141 made of silicon dioxide is disposed directly above the piezoelectric substrate 110 in the cover layer 140. This arrangement can improve the temperature characteristics of the SAW resonator formed by the IDT electrodes 131, 132, and thus of the SAW filter 100. Further, because the first lower-sound-velocity layer 122 is disposed directly under and in contact with the piezoelectric substrate 110 and the third lower-sound-velocity layer 141 is disposed directly above and in contact with the piezoelectric substrate 110, the SAW resonator formed by the IDT electrodes 131, 132, and thus the SAW filter 100, can be less sensitive to the thickness of the piezoelectric substrate 110.

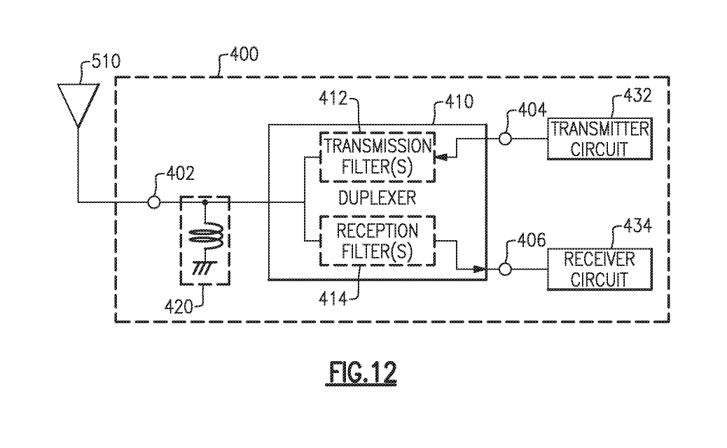

FIG. 10 is a cross-sectional view showing a schematic structure of another example of the SAW filter 100 according to certain embodiments. In this example the support substrate 120 includes a first structural layer 121 and a first lower-sound-velocity layer 122 stacked on the first structural layer 121. In addition, a cover layer 140 is formed to include a second structural layer 142 and a third lower-sound-velocity layer 141 both stacked on the piezoelectric substrate 110.

According to the example of FIG. 10, the piezoelectric substrate 110 is made of piezoelectric body such as lithium niobate or lithium tantalate and is supported by the support substrate 120. As discussed above, the support substrate 120 includes the first structural layer 121 made of silicon, sapphire or diamond and having a certain thickness for providing a structure to mechanically support the piezoelectric substrate 110. The support substrate 120 further includes the first lower-sound-velocity layer 122 disposed on a top surface of the first structural layer 121. The first lower-sound-velocity layer 122 has a certain thickness, is made of silicon dioxide, and is characterized by a sound velocity lower than that of the first structural layer 121. Thus, the first structural layer 121 may be referred to as a higher-sound-velocity layer because it is characterized by a sound velocity higher than that of the first lower-sound-velocity layer 122.

In the example of FIG. 10, a plurality of IDT electrodes 131, 132 are formed on the top surfaces of the piezoelectric substrate 110, similar to the example shown in FIG. 9. Further, the cover layer 140 defining a certain height is disposed on the top surfaces of the piezoelectric substrate 110 to cover the IDT electrodes 131, 132. The cover layer 140 includes a third lower-sound-velocity layer 141 having a certain thickness, made of silicon dioxide, and characterized by a sound velocity lower than that of the first structural layer 121. The cover layer 140 further includes a second structural layer 142 disposed on a top surface of the third lower-sound-velocity layer 141, made of silicon, sapphire or diamond, and having a certain thickness for providing a structure to mechanically support the piezoelectric substrate 110.

Also in this example, the piezoelectric substrate 110 has a flat bottom surface abutting the support substrate 120 and top surfaces arranged at different suitable heights (H₁, H₂) above the flat bottom surface. As discussed above, the different heights (H₁, H₂) are defined such that respective regions of the piezoelectric substrate 110 where each of the IDT electrodes 131, 132 are disposed can have suitable thicknesses depending on a pitch of the corresponding IDT electrode. Therefore, the performance of the SAW resonator formed by the IDT electrodes 131, 132 can be improved, and thus the performance of the SAW filter 100 can be improved as well.

In the example of FIG. 10, the first lower-sound-velocity layer 122 is made of silicon dioxide and is disposed directly under and abutting the piezoelectric substrate 110 in the support substrate 120. The third lower-sound-velocity layer 141 is made of silicon dioxide and is disposed directly above and abutting the piezoelectric substrate 110 in the cover layer 140. This arrangement can improve the temperature characteristics of the SAW resonator formed by the IDT electrodes 131, 132 and thus of the SAW filter 100. Further, because the first lower-sound-velocity layer 122 is disposed directly under and in contact with the piezoelectric substrate 110 and the third lower-sound-velocity layer 141 is disposed directly above and in contact with the piezoelectric substrate 110, the SAW resonator formed by the IDT electrodes 131, 132, and thus the SAW filter 100, may be less sensitive to the thickness of the piezoelectric substrate 110.

Also in the example of FIG. 10, the first structural layer 121 supports the bottom surface of the first lower-sound-velocity layer 122 in the support substrate 120, and the second structural layer 142 covers the top surface of the third lower-sound-velocity layer 141 in the cover layer 140. Therefore, the mold resistance of such examples of the SAW filter 100 having a cavity-less structure can be improved, and accordingly downsizing of the SAW filter can be realized.

Embodiments of the SAW filter 100 may be incorporated into and packaged as a module that may ultimately be used in an electronic device, such as a wireless communications device, for example. FIG. 11 is a block diagram illustrating one example of a module 300 including the SAW filter 100. The SAW filter 100 may be implemented on one or more die(s) 310 including one or more connection pads 312. For example, the SAW filter 100 may include a connection pad 312 that corresponds to an input contact for the SAW filter and another connection pad 312 that corresponds to an output contact for the SAW filter. The packaged module 300 includes a packaging substrate 320 that is configured to receive a plurality of components, including the die 310. A plurality of connection pads 322 can be disposed on the packaging substrate 320, and the various connection pads 312 of the SAW filter die 310 can be connected to the connection pads 322 on the packaging substrate 320 via electrical connectors 324, which can be solder bumps or wirebonds, for example, to allow for passing of various signals to and from the SAW filter 100. The module 300 may optionally further include other circuitry die 330, such as, for example one or more additional filter(s), amplifiers, pre-filters, modulators, demodulators, down converters, and the like, as would be known to one of skill in the art of semiconductor fabrication in view of the disclosure herein. In some embodiments, the module 300 can also include one or more packaging structures to, for example, provide protection and facilitate easier handling of the module 300. Such a packaging structure can include an overmold formed over the packaging substrate 320 and dimensioned to substantially encapsulate the various circuits and components thereon.

As discussed above, various examples and embodiments of the SAW filter 100 can be used in a wide variety of electronic devices. For example, the SAW filter 100 can be used in an antenna duplexer, which itself can be incorporated into a variety of electronic devices, such as RF front-end modules and communications devices.

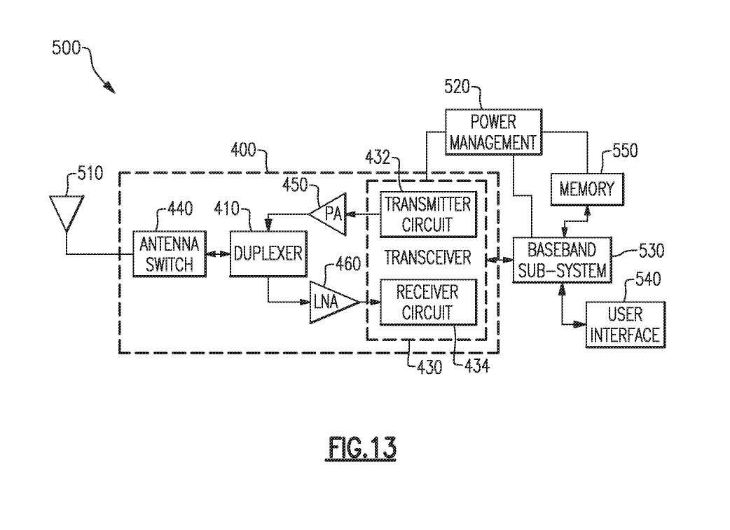

Referring to FIG. 12, there is illustrated a block diagram of one example of a front-end module 400, which may be used in an electronic device such as a wireless communications device (e.g., a mobile phone) for example. The front-end module 400 includes an antenna duplexer 410 having a common node 402, an input node 404, and an output node 406. An antenna 510 is connected to the common node 402.

The antenna duplexer 410 may include one or more transmission filters 412 connected between the input node 404 and the common node 402, and one or more reception filters 414 connected between the common node 402 and the output node 406. The passband(s) of the transmission filter(s) are different from the passband(s) of the reception filter(s). As discussed above, the SAW filter 100 can include a first plurality of IDT electrodes that are arranged to form the transmission filter(s) 412 and a second plurality of IDT electrodes that are arranged to form the reception filter(s) 414. An inductor or other matching component 420 may be connected at the common node 402.

The front-end module 400 further includes a transmitter circuit 432 connected to the input node 404 of the duplexer 410 and a receiver circuit 434 connected to the output node 406 of the duplexer 410. The transmitter circuit 432 can generate signals for transmission via the antenna 510, and the receiver circuit 434 can receive and process signals received via the antenna 410. In some embodiments, the receiver and transmitter circuits are implemented as separate components, as shown in FIG. 12, however in other embodiments these components may be integrated into a common transceiver circuit or module. As will be appreciated by those skilled in the art, the front-end module 400 may include other components that are not illustrated in FIG. 12 including, but not limited to, switches, electromagnetic couplers, amplifiers, processors, and the like.

FIG. 13 is a block diagram of one example of a wireless device 500 including the antenna duplexer 410 shown in FIG. 12. The wireless device 500 can be a cellular phone, smart phone, tablet, modem, communications network or any other portable or non-portable device configured for voice or data communication. The wireless device 500 can receive and transmit signals from the antenna 510. The wireless device includes an embodiment of a front-end module 400 similar to that discussed above with reference to FIG. 12. The front-end module 400 includes the duplexer 410, as discussed above. In the example shown in FIG. 13 the front-end module 400 further includes an antenna switch 440, which can be configured to switch between different frequency bands or modes, such as transmit and receive modes, for example. In the example illustrated in FIG. 13, the antenna switch 440 is positioned between the duplexer 410 and the antenna 510; however, in other examples the duplexer 410 can be positioned between the antenna switch 440 and the antenna 510. In other examples the antenna switch 440 and the duplexer 410 can be integrated into a single component.

The front-end module 400 includes a transceiver 430 that is configured to generate signals for transmission or to process received signals. The transceiver 430 can include the transmitter circuit 432, which can be connected to the input node 404 of the duplexer 410, and the receiver circuit 434, which can be connected to the output node 406 of the duplexer 410, as shown in the example of FIG. 12.

Signals generated for transmission by the transmitter circuit 432 are received by a power amplifier (PA) module 450, which amplifies the generated signals from the transmitter circuit 432 of the transceiver 430. The power amplifier module 450 can include one or more power amplifiers. The power amplifier module 450 can be used to amplify a wide variety of RF or other frequency-band transmission signals. For example, the power amplifier module 450 can receive an enable signal that can be used to pulse the output of the power amplifier to aid in transmitting a wireless local area network (WLAN) signal or any other suitable pulsed signal. The power amplifier module 450 can be configured to amplify any of a variety of types of signal, including, for example, a Global System for Mobile (GSM) signal, a code division multiple access (CDMA) signal, a W-CDMA signal, a Long-Term Evolution (LTE) signal, or an EDGE signal. In certain embodiments, the power amplifier module 450 and associated components including switches and the like can be fabricated on gallium arsenide (GaAs) substrates using, for example, high-electron mobility transistors (pHEMT) or insulated-gate bipolar transistors (BiFET), or on a Silicon substrate using complementary metal-oxide semiconductor (CMOS) field effect transistors.

Still referring to FIG. 13, the front-end module 400 may further include a low noise amplifier module 460, which amplifies received signals from the antenna 510 and provides the amplified signals to the receiver circuit 434 of the transceiver 430.

The wireless device 500 of FIG. 13 further includes a power management sub-system 520 that is connected to the transceiver 430 and manages the power for the operation of the wireless device 500. The power management system 520 can also control the operation of a baseband sub-system 530 and various other components of the wireless device 500. The power management system 520 can include, or can be connected to, a battery (not shown) that supplies power for the various components of the wireless device 500. The power management system 520 can further include one or more processors or controllers that can control the transmission of signals, for example. In one embodiment, the baseband sub-system 530 is connected to a user interface 540 to facilitate various input and output of voice and/or data provided to and received from the user. The baseband sub-system 530 can also be connected to memory 550 that is configured to store data and/or instructions to facilitate the operation of the wireless device, and/or to provide storage of information for the user.

Having described above several aspects of at least one embodiment, it is to be appreciated various alterations, modifications, and improvements will readily occur to those skilled in the art. Such alterations, modifications, and improvements are intended to be part of this disclosure and are intended to be within the scope of the invention. It is to be appreciated that embodiments of the methods and apparatuses discussed herein are not limited in application to the details of construction and the arrangement of components set forth in the description or illustrated in the accompanying drawings. The methods and apparatuses are capable of implementation in other embodiments and of being practiced or of being carried out in various ways. Examples of specific implementations are provided herein for illustrative purposes only and are not intended to be limiting. Also, the phraseology and terminology used herein is for the purpose of description and should not be regarded as limiting. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms. Any references to front and back, left and right, top and bottom, upper and lower, and vertical and horizontal are intended for convenience of description, not to limit the present systems and methods or their components to any one positional or spatial orientation Accordingly, the foregoing description and drawings are by way of example only, and the scope of the invention should be determined from proper construction of the appended claims, and their equivalents.

What is claimed is:

1. A surface acoustic wave (SAW) filter comprising:
a support substrate including a first structural layer;
a piezoelectric substrate disposed on and mechanically supported by the support substrate, the piezoelectric substrate including a first region having a first thickness and a second region having a second thickness different from the first thickness; and
a plurality of interdigital transducer (IDT) electrodes disposed on the piezoelectric substrate, a first IDT electrode of the plurality of IDT electrodes being disposed on the first region of the piezoelectric substrate and a second IDT electrode of the plurality of IDT electrodes being disposed on the second region of the piezoelectric substrate, the first IDT electrode including first IDT electrode fingers having a first pitch, and the second IDT electrode including second IDT electrode fingers having a second pitch, the second pitch being different from the first pitch.

2. The SAW filter of claim 1 wherein the first pitch is greater than the second pitch, and the first thickness is greater than the second thickness.

3. The SAW filter of claim 1 wherein the piezoelectric substrate has a first surface abutting the support substrate and a second surface, the second surface being disposed at a first height above the first surface in the first region and at a second height above the first surface in the second region, the first height being defined by the first thickness and the second height being defined by the second thickness.

4. The SAW filter of claim 1 wherein the piezoelectric substrate has a first flat surface and a second surface that abuts the support substrate, the second surface being disposed a first distance away from the flat first surface in the first region and a second distance away from the flat first surface in the second region, the first distance being defined by the first thickness and the second distance being defined by the second thickness.

5. The SAW filter of claim 1 wherein the support substrate further includes a second structural layer interposed between the first structural layer and the piezoelectric substrate, the second structural layer having a lower sound velocity than the first structural layer.

6. The SAW filter of claim 6 wherein the first structural layer is made of one of silicon, sapphire, or diamond, and the second structural layer is made of silicon dioxide.

7. The SAW filter of claim 6 wherein the support substrate further includes at least one spacer configured to space the second structural layer apart from the first structural layer to form a gap layer positioned between the first structural layer and the second structural layer, the gap layer being configured to reflect at least one acoustic wave within the second structural layer.

8. The SAW filter of claim 7 wherein the gap layer is an air gap layer.

9. The SAW filter of claim 1 further comprising a cover layer disposed on the piezoelectric substrate.

10. The SAW filter of claim 9 wherein the cover layer has a lower sound velocity than the first structural layer.

11. The SAW filter of claim 10 wherein the cover layer is made of silicon dioxide.

12. The SAW filter of claim 9 wherein the cover layer includes a second structural layer, the second structural layer being made of one of silicon, sapphire, and diamond.

13. The SAW filter of claim 1 wherein the support substrate includes stack of a plurality of the first structural layers and a plurality of second layers alternately arranged abutting one another, the stack being configured to reflect at least one acoustic wave towards the piezoelectric substrate, each of the plurality of first structural layers having a first sound velocity and each of the plurality of second layers having a second sound velocity, the first sound velocity being lower than the second sound velocity.

14. The SAW filter of claim 13 wherein each of the plurality of first structural layers is made of one of silicon, sapphire, and diamond, and each of the plurality of second layers is made of silicon dioxide.

15. A ladder-type surface acoustic wave (SAW) filter comprising:
a support substrate including a first structural layer;
a piezoelectric substrate disposed on and mechanically supported by the support substrate, the piezoelectric substrate including a first region having a first thickness and a second region having a second thickness different from the first thickness; and
a plurality of series-arm resonators connected in series with one another along a signal path extending between an input of the ladder-type SAW filter and an output of the ladder-type SAW filter, the plurality of series-arm resonators being disposed on the first region of the piezoelectric substrate; and
a plurality of parallel-arm resonators connected between the signal path and a ground, the plurality of parallel-arm resonator being disposed on the second region of the piezoelectric substrate.

16. The ladder-type SAW filter of claim 15 wherein at least one series-arm resonator of the plurality of series-arm resonators includes a first interdigital transducer (IDT) electrode having first IDT electrode fingers arranged with a first pitch, and at least one parallel-arm resonator of the plurality of parallel-arm resonators includes a second IDT electrode having second IDT electrode fingers arranged with a second pitch, the second pitch being different from the first pitch.

17. The ladder-type SAW filter of claim 16 wherein the first pitch is greater than the second pitch, and the first thickness is greater than the second thickness.

18. The ladder-type SAW filter of claim 15 wherein the support substrate further includes a second structural layer interposed between the first structural layer and the piezoelectric substrate, the second structural layer having a lower sound velocity than the first structural layer.

19. An antenna duplexer comprising:
an input contact, an output contact, and a common contact;
a support substrate;
a piezoelectric substrate disposed on and mechanically supported by the support substrate, the piezoelectric substrate including a first region having a first thickness and a second region having a second thickness different from the first thickness;
a transmission filter connected between the input contact and the common contact, the transmission filter including at least one transmission resonator having a first interdigital transducer (IDT) electrode disposed on the first region of the piezoelectric substrate; and
a reception filter connected between the common contact and the output contact, the reception filter including at least one reception resonator having a second IDT electrode disposed on the second region of the piezoelectric substrate.

20. The antenna duplexer of claim 19 wherein the first thickness is less than the second thickness, the first IDT electrode has a first electrode-finger pitch, and the second IDT electrode has a second electrode-finger pitch that is greater than the first electrode-finger pitch.
